(19) United States
(12) Patent Application Publication
(10) Pub. No.: US 2004/0157461 A1
(43) Pub. Date: Aug. 12, 2004

(54) Method for fabricating a wafer including dry etching the edge of the wafer

(75) Inventors: Oleg V. Kononchuk, Brush Prairie, WA (US); Yi Pan, Vancouver, WA (US); Brazel G. Preece, Vancouver, WA (US)

Correspondence Address: ALSTON & BIRD LLP, BANK OF AMERICA PLAZA, 101 SOUTH TRYON STREET, SUITE 4000, CHARLOTTE, NC, 28280-4000, US

(73) Assignee: SEH America, Inc.

(21) Appl. No.: 10/361,280

(22) Filed: Feb. 10, 2003

(51) Int. Cl. H01L 21/302; H01L 21/461

(52) U.S. Cl. 438/710

(57) ABSTRACT

A method for fabricating a wafer including an improved method for processing the edge of a wafer that utilizes dry etching techniques is provided. In this regard, the profile of the edge of the wafer may initially be defined, such as by rounding or chamfering the edge of the wafer. The wafer edge may then be dry etched, such as by atmospheric downstream plasma (ADP) etching, chemical downstream etching (CDE) or the like, in order to smooth the edge of the wafer while eliminating, or reducing, the use of wet chemical etchants. In addition, one or both major surfaces of the wafer may be dry etched, also with ADP etching or CDE, to further reduce the use of wet chemical etchants. Wafers fabricated according to this method are also provided.

### FIELD OF THE INVENTION

The present invention relates generally to methods for fabricating wafers and, more particularly, to methods for fabricating wafers that dry etch the edge of the wafer in order to at least partially smooth the edge of the wafer.

### BACKGROUND OF THE INVENTION

Wafers, such as silicon wafers, that form the substrate upon which semiconductor devices are formed must be made to exact specifications and must be generally free of manufacturing defects. During a typical wafer fabrication process, wafers are sliced from an ingot. Thereafter, the wafer edge is ground to size the wafer to an exact diameter and to form the edges into a preferred geometric shape. In this regard, the edge is generally ground to define chamfered portions proximate each of the opposed major surfaces. This grinding process, however, can create cracks and imperfections in the wafer which, in the ensuing machining processes, can propagate from the edge toward interior regions of the wafer upon which semiconductor devices will subsequently be formed.

These imperfections can render all or portions of the wafer useless for subsequent semiconductor device fabrication and significantly diminish the yield of useful wafers obtained from an ingot. In addition, subsequent high temperature annealing processes can cause wafers in which the cracks, fractures or the like have propagated into the interior of the wafer to break in the furnace. In this event, the furnace must soon be shut down, cooled, cleaned out, and reheated which significantly delays the fabrication process and may consume an entire day. Such delays are obviously costly to the wafer fabrication process. Because of such potential degradation, if not destruction, of the wafer, it is desirable to etch and/or polish the wafer edge so that the wafer edge is defect-free down to a microscopic level.

Prior to etching and/or polishing the edge of the wafer in a conventional wafer fabrication process, material is generally removed from the opposed major surfaces, such as by lapping or grinding. The lapping or grinding serves to planarize the wafer, thereby improving the flatness of the wafer and reducing thickness variations. Thereafter, the opposed surfaces are etched in order to reduce surface defects. The wafer edge may then also be etched.

The etching of the opposed major surfaces and the wafer edge utilizes wet chemical etchants, such as acidic and/or alkaline chemical etching agents. Many of these etchants are hazardous chemicals that require special handling, including special storage and disposal. Additionally, many of these etchants pose safety concerns, especially for technicians that come into contact with them. Further, the wet chemical etchants may be quite expensive, thereby increasing the overall cost of the resulting wafers.

Following the chemical etching process, the wafers may be rinsed, thermally processed, and inspected. Following inspection, the edges are polished such that the resulting edge surfaces have a mirror-like finish that resists the subsequent adhesion of contaminants. Thereafter, at least the front surface of the wafer can also be polished, usually by means of a polishing machine that sequentially employs slurry having particulates of decreasing size in order to finely polish the front surface.

Although conventional wafer fabrication processes produce wafers that are generally acceptable for current applications, the specifications for the semiconductor devices that are eventually formed upon the wafers, as well as the specifications for the wafers themselves, are continually being tightened, both in terms of technical and performance specifications and in terms of cost. As such, it would be desirable to develop a process for fabricating wafers that is less expensive, but that produces wafers that could meet even more stringent specifications and tighter tolerances. In addition, it would be desirable to reduce, if not eliminate, the adverse environmental impact occasioned by the disposal of wet chemical etchants, as well as the costs and safety concerns raised by the storage, use, treatment and disposal of the wet chemical etchants.

### BRIEF SUMMARY OF THE INVENTION

An improved method for fabricating a wafer including an improved method for processing the edge of a wafer is provided in accordance with embodiments of the present invention. In this regard, the method of the present invention dry etches the edge of the wafer in order to at least partially smooth the edge of the wafer. In some embodiments, at least one major surface of the wafer may also be dry etched. By dry etching the edge of the wafer and, in some embodiments, at least one major surface of the wafer, the use of wet chemical etchants can be reduced, if not eliminated, thereby improving the safety of the wafer fabrication process and reducing its environmental impact. In addition, the costs of the wafer fabrication process and, in turn, the wafers produced by the wafer fabrication process may be reduced as a result of the reduction, if not elimination, of wet chemical etching. Moreover, the dry etching of the edge of the wafer and, in some embodiments, at least one major surface of the wafer permits the wafer to be more precisely fabricated, such as by reducing surface roughness and thickness variations. As such, the wafer fabrication method of embodiments of the present invention may provide improved wafer quality relative to conventional fabrication techniques.

According to one aspect of the present invention, a method of processing the edge of a wafer is provided that first defines the initial profile of the edge of the wafer. For example, the edge of the wafer may be rounded. Alternatively, the edge of the wafer may be chamfered, such as grinding the edge of the wafer to have a predefined angle relative to at least one major surface of the wafer. Thereafter, the edge of the wafer is dry etched to at least partially smooth the edge of the wafer. For example, the edge of the wafer may be plasma etched, such as by atmospheric downstream plasma etching techniques. Thus, the edge of wafer may be smoothed without requiring the use of wet chemical etchants and incurring the disadvantageous environmental, safety and costs concerns associated with wet chemical etchants. Although the dry etching of the edge of the wafer may be sufficient to complete the processing of the edge of the wafer, the method of one embodiment of the present invention also polishes the edge of the wafer following the dry etching.

In addition to processing the edge of wafer, other aspects of the present invention provide a method for fabricating a wafer that includes dry etching the edge of the wafer. According to these aspects of the present invention, the wafer is fabricated by removing material from at least one major surface of the wafer by either lapping, grinding or etching. In embodiments in which at least one major surface of the wafer is etched, at least one major surface may be dry-etched, such as by atmospheric downstream plasma etching, chemical downstream etching or other dry etching techniques. By utilizing a dry etching technique, the environmental and safety issues occasioned by use of a wet chemical etchant are eliminated, and the cost may be reduced. Additionally, the dry etching may produce a wafer of higher quality having greater flatness and reduced thickness variations than those produced in accordance with conventional wet etching techniques. Thereafter, the method of fabricating a wafer polishes at least one major surface of the wafer.

The method of this aspect of the present invention not only etches and polishes the major surface(s) of the wafer, but also processes the edge of the wafer. Prior to polishing, for example, an edge of the wafer is dry etched, such as by atmospheric downstream plasma etching, in order to at least partially smooth the edge of the wafer. In this regard, the dry etching of the edge of the wafer may occur either prior to or following the removal of material from at least one major surface of the wafer. Following the dry etching of the edge of the wafer, the edge of the wafer may be polished prior to similarly polishing at least one major surface of the wafer. Additionally, the edge of the wafer may be processed prior to dry etching the edge of the wafer, such as by defining the initial profile of the edge of the wafer by either rounding the edge of the wafer or chamfering the edge of the wafer.

As described, dry etching the edge of the wafer permits the environmental and safety issues occasioned by conventional wet etching techniques to be eliminated, and the cost of the resulting wafers to potentially be reduced, while concurrently improving the quality of the resulting wafers. In accordance with other aspects of the present invention, a wafer fabricated in accordance with the method of the present invention is also provided.

### BRIEF DESCRIPTION OF THE SEVERAL VIEWS OF THE DRAWING(S)

Having thus described the invention in general terms, reference will now be made to the accompanying drawings, which are not necessarily drawn to scale, and wherein:

FIG. 1 is a flow chart illustrating the operations performed in accordance with one embodiment of the present invention; and

FIG. 2 is a schematic representation of a plurality of wafers undergoing plasma etching in accordance with one embodiment to the present invention.

### DETAILED DESCRIPTION OF THE INVENTION

The present inventions now will be described more fully hereinafter with reference to the accompanying drawings, in which some, but not all embodiments of the invention are shown. Indeed, these inventions may be embodied in many different forms and should not be construed as limited to the embodiments set forth herein; rather, these embodiments are provided so that this disclosure will satisfy applicable legal requirements. Like numbers refer to like elements throughout.

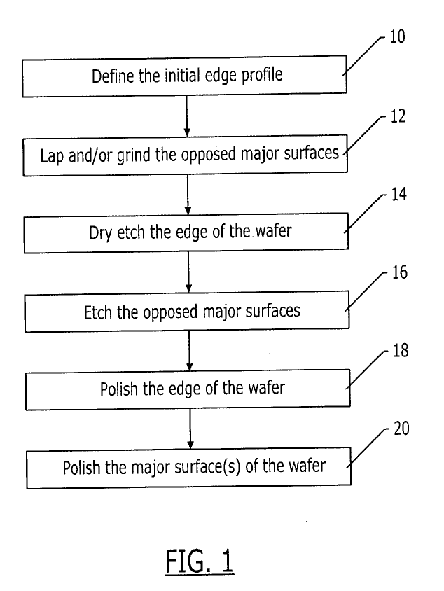

As depicted in FIG. 1, a method of fabricating a wafer that includes a method of processing the edge of the wafer is provided according to the present invention. The method may be utilized to fabricate a variety of wafers, including wafers having various sizes or diameters and wafers comprised of various materials, including silicon wafers that have been appropriately doped with either an n-type dopant or a p-type dopant. Prior to commencing the method of the present invention, individual wafers are formed in accordance with any of a variety of conventional techniques. For example, a crystal ingot may be sliced into a plurality of wafers that are thereafter processed in accordance with the method of the present invention. Moreover, while the method of the present invention will be described hereinbelow in conjunction with the fabrication of a single wafer, the method of the present invention may also be utilized in a batch mode in which multiple wafers are concurrently processed in either all or some of the process steps.

As shown in block 10 of FIG. 1, the edge of the wafer may initially be processed to define an initial profile of the edge of a wafer. For example, the edge of the wafer may be rounded, such as by grinding the edge of the wafer with a grinding wheel or the like that defines the desired rounded profile of the edge of the wafer. Alternatively, the edge of the wafer may be chamfered. In this regard, the edge of the wafer may be ground to have a predefined angle relative to at least one major surface of the wafer. While wafers having edges with various profiles may be fabricated in accordance with the method of the present invention, the chamfered edge of one wafer includes oppositely chamfered portions proximate the opposed major surfaces with each chamfered portion defining the same predefined angle relative to the respective major surface, such as a predefined angle of 11°, 22° or the like. The chamfered edge of the wafer of this exemplary embodiment may be defined such that the oppositely chamfered portions are separated by a medial edge portion that generally extends perpendicular to the opposed major surfaces of the wafer. Regardless of the technique by which the initial profile of the edge of the wafer is defined, this initial processing of the edge of the wafer not only generally defines the desired profile of the edge of the wafer, but also more accurately sizes and shapes the wafer to ensure that the method of the present invention produces wafers of the desired shape and size.

Material is then removed from at least one major surface of the wafer in order to generally planarize at least one major surface. Typically, material is removed from both of the opposed major surfaces in order to planarize the front and rear surfaces of the wafer. By planarizing the front and rear surfaces of the wafer, the flatness of the opposed surfaces is improved and thickness variations are reduced. Material may be removed from at least one major surface of the wafer in accordance with various techniques, including lapping, grinding and combinations thereof. As depicted in FIG. 1, for example, the opposed major surfaces may initially be either lapped or ground to generally planarize the opposed major surfaces, as shown in block 12.

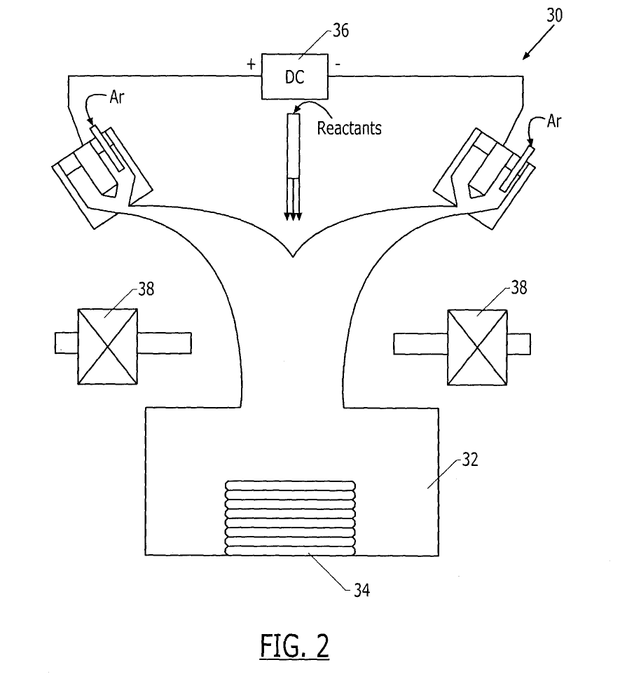

As illustrated in block 14 of FIG. 1 and in accordance with one embodiment of the present invention, the edge of the wafer is then dry etched in order to at least partially smooth the edge of the wafer. Various techniques may be utilized to dry etch the edge of the wafer, including plasma etching, such as atmospheric downstream plasma (ADP) etching. As known to those skilled in the art, ADP etching utilizes an argon plasma at high temperature, but at atmospheric pressure. For example, the wafer may be loaded into a wafer etching system, such as those provided by Tru-Si Technologies, Inc. of Sunnyvale, Calif., including, for example, a Tru-Etch 3000 system such that the edge of the wafer is ADP etched. In this regard, FIG. 2 depicts an ADP plasma source 30 and an associated reaction chamber 32 in which one or more wafers could be loaded in order to ADP etch the edge of the wafer(s). In FIG. 2, for example, a plurality of wafers 34 are coinstacked such that only the edges of the intermediate wafers are exposed. While the plurality of coinstacked wafers are disposed immediately adjacent one another, spacers may be disposed between some or all of the wafers in order to separate the wafers and protect the major surfaces of the wafers, if desired. The plurality of coinstacked wafers are disposed within the reaction chamber that is maintained at atmospheric pressure, but generally at an elevated temperature, such that the wafers are maintained at a temperature of about 160° C. to about 300° C. In accordance with the embodiment depicted in FIG. 2, the ADP source includes a DC power supply 36 to create a DC-arc plasma discharge in the presence of argon and various reactants, such as carbon tetrafluoride and oxygen. The plasma discharged is controlled by a magnetic field generated by a plurality of electromagnets 38 in order to ADP etch the edges of the coinstacked wafers in the reaction chamber, typically at an etch rate up to 3 μm/min. Further details regarding ADP etching are provided by www.trusi.com.

Although ADP etching is advantageous for smoothing the edges of a wafer, other dry etching techniques may be utilized, including chemical downstream etching, either independent of or in combination with reactive ion etching. As known to those skilled in the art, chemical downstream etching utilizes microwave excited plasma and fluorine compounds, such as CF₄, SF₆ or NF₃, to etch a surface at reduced pressure. Although not necessary, the chemical downstream etching may be employed in conjunction with reactive ion etching, also at reduced pressures, if so desired.

Dry etching, such as ADP etching, provides a very controllable etch of the edge of the wafer. In addition, the use of dry etching eliminates issues relating to safety and the environmental impact of wet chemical etching and generally also reduces the cost of the resulting wafers. While the dry etching preferably eliminates wet chemical etching of the wafer edge, both wet and dry etching may be performed in some embodiments with the dry etching serving to reduce the extent of the wet etching required.

Following the dry etching of the edge of the wafer, the major surface(s) are etched to remove residual surface damage as shown in block 16, such as surface damage attributable at least in part to the lapping or grinding process, and to remove contamination therefrom. According to one advantageous embodiment to the present invention, the surface(s) of the wafer are etched in accordance with a dry etching technique. Various dry etching techniques may be utilized, including plasma etching such as ADP. As described above and as depicted in FIG. 2 in conjunction with the ADP etching of the edge of a wafer, the wafer may be loaded into a wafer etching system, such as those provided by Tru-Si Technologies, Inc. of Sunnyvale, Calif., including, for example, a Tru-Etch 3000 system such that one or both major surfaces may be ADP etched.

According to this aspect of the present invention, the major surface(s) may alternatively be dry etched in accordance with other techniques, including chemical downstream etching. Although not necessary, the chemical downstream etching may be employed in conjunction with reactive ion etching, also at reduced pressures, if so desired. Regardless of the type of dry etching, the entire major surface of the wafer is advantageously etched at one time in order to expedite the etching process. As a result of the dry etching of the major surface(s) of the wafer, the resulting wafer will be of relatively high quality and will generally have reduced thickness variations and improved flatness relative to wafers fabricated in accordance with conventional wet chemical etching processes. In addition, the use of dry etching eliminates concern regarding safety and environmental issues and generally also reduces the cost of the resulting wafers. While the dry etching preferably eliminates wet chemical etching of the major surfaces of the wafer, both wet and dry etching may be performed with the dry etching serving to reduce the extent of the wet etching required.

Thereafter, the edge of the wafer is typically polished as shown by block 18 of FIG. 1. Edge polishing serves to further smooth the edge of the wafer, thereby further eliminating defects and contaminants on the edge of the wafer. However, the dry etching of the edge of the wafer may produce an edge that is sufficiently smooth and defect-free so as to forego the edge polishing or at least reduce the amount of edge polishing that is required for at least some wafers.

The major surface(s) of the wafer are then polished as shown by block 20 of FIG. 1. As known to those skilled in the art, the major surface(s) of the wafer are typically polished in a sequential manner utilizing slurries having abrasive particles of increasingly smaller sizes until the major surface(s) of the wafer have a mirror-like appearance. As known to those skilled in the art and depending upon the intended application of the wafer, the resulting wafers may be either single side polished in which only the front surface of the wafer is polished, or double side polished in which both the front and rear surfaces of the wafer are polished. Following polishing of the major surface(s) of the wafer, the wafer is typically cleaned to remove the polishing slurry and the like, thereby effectively completing the wafer fabrication process.

As illustrated in FIG. 1 and as described above, the dry etch of the edge of a wafer may occur following the removal of material from the major surface(s) of the wafer, but prior to the etching and polishing of the major surface(s) of the wafer. However, the dry etch of the edge of the wafer may actually occur following the etching of the major surface(s) of the wafer, if desired.

Regardless of the sequence of operations, the dry etching of the edge of the wafer and, in some embodiments, the major surface(s) of the wafer eliminates, or at least reduces, the use of wet chemical etching, thereby avoiding the environmental and safety issues raised by wet chemical etchants, while improving the quality of the wafer, both in terms of flatness and reduced thickness variations. In addition, the cost of the resulting wafer may be reduced in comparison to wafers fabricated in accordance with processes requiring wet chemical etching, especially in instances in which the dry edge etch sufficiently smoothes the edge such that no, or only a limited amount of, edge polishing is required.

Many modifications and other embodiments of the inventions set forth herein will come to mind to one skilled in the art to which these inventions pertain having the benefit of the teachings presented in the foregoing descriptions and the associated drawings. Therefore, it is to be understood that the inventions are not to be limited to the specific embodiments disclosed and that modifications and other embodiments are intended to be included within the scope of the appended claims. Although specific terms are employed herein, they are used in a generic and descriptive sense only and not for purposes of limitation.

That which is claimed:

1. A method of fabricating a wafer comprising:
removing material from at least one major surface of the wafer in accordance with a technique selected from the group consisting of lapping, grinding and etching the at least one major surface of the wafer;
thereafter polishing at least one major surface of the wafer; and
dry etching an edge of the wafer prior to polishing the at least one major surface of the wafer in order to at least partially smooth the edge of the wafer.

2. A method according to claim 1 wherein dry etching the edge of the wafer comprises plasma etching the edge of the wafer.

3. A method according to claim 2 wherein plasma etching the edge of the wafer comprises conducting atmospheric downstream plasma etching of the edge of the wafer.

4. A method according to claim 1 further comprising polishing the edge of the wafer following the dry etching of the edge of the wafer.

5. A method according to claim 1 further comprising defining an initial profile of the edge of the wafer in accordance with a technique selected from the group consisting of rounding the edge of the wafer and chamfering the edge of the wafer, wherein defining the initial profile of the edge of the wafer precedes the dry etching of the edge of the wafer.

6. A method according to claim 1 wherein dry etching the edge of the wafer precedes the removal of material from the at least one major surface of the wafer.

7. A method according to claim 1 wherein dry etching the edge of the wafer follows the removal of material from the at least one major surface of the wafer.

8. A method according to claim 1 wherein the removal of material from the at least one major surface of the wafer comprises dry etching the at least one major surface.

9. A method according to claim 8 wherein dry etching the at least one major surface comprises conducting a dry etching technique selected from the group consisting of atmospheric downstream plasma etching and chemical downstream etching.

10. A method of processing an edge of a wafer comprising:
defining an initial profile of the edge of the wafer; and
dry etching the edge of the wafer following the definition of the initial profile of the edge to at least partially smooth the edge of the wafer.

11. A method according to claim 10 wherein dry etching the edge of the wafer comprises plasma etching the edge of the wafer.

12. A method according to claim 11 wherein plasma etching the edge of the wafer comprises conducting atmospheric downstream plasma etching of the edge of the wafer.

13. A method according to claim 10 further comprising polishing the edge of the wafer following the dry etching of the edge of the wafer.

14. A method according to claim 10 wherein defining the initial profile of the edge of the wafer comprises rounding the edge of the wafer.

15. A method according to claim 10 wherein defining the initial profile of the edge of the wafer comprises chamfering the edge of the wafer.

16. A method according to claim 15 wherein chamfering the edge of the wafer comprises grinding the edge of the wafer to have a predefined angle relative to at least one major surface of the wafer.

17. A wafer fabricated according to a method comprising:
removing material from at least one major surface of the wafer in accordance with a technique selected from the group consisting of lapping, grinding and etching the at least one major surface of the wafer;
thereafter polishing at least one major surface of the wafer; and
dry etching an edge of the wafer prior to polishing the at least one major surface of the wafer in order to at least partially smooth the edge of the wafer.

18. A wafer fabricated according to the method of claim 17 wherein dry etching the edge of the wafer comprises plasma etching the edge of the wafer.

19. A wafer fabricated according to the method of claim 18 wherein plasma etching the edge of the wafer comprises conducting atmospheric downstream plasma etching of the edge of the wafer.

20. A wafer fabricated according to the method of claim 17 further comprising polishing the edge of the wafer following the dry etching of the edge of the wafer.

21. A wafer fabricated according to the method of claim 17 further comprising defining an initial profile of the edge of the wafer in accordance with a technique selected from the group consisting of rounding the edge of the wafer and chamfering the edge of the wafer, wherein defining the initial profile of the edge of the wafer precedes the dry etching of the edge of the wafer.

22. A wafer fabricated according to the method of claim 17 wherein dry etching the edge of the wafer precedes the removal of material from the at least one major surface of the wafer.

23. A wafer fabricated according to the method of claim 17 wherein dry etching the edge of the wafer follows the removal of material from the at least one major surface of the wafer.

24. A wafer fabricated according to the method of claim 17 wherein the removal of material from the at least one major surface of the wafer comprises dry etching the at least one major surface.

25. A wafer fabricated according to the method of claim 24 wherein dry etching the at least one major surface comprises conducting a dry etching technique selected from the group consisting of atmospheric downstream plasma etching and chemical downstream etching.
